(19) United States
(12) Patent Application Publication
(10) Pub. No.: US 2007/0278502 A1
(43) Pub. Date: Dec. 6, 2007

(54) Semiconductor Light Emitting Device

(75) Inventors: Yukio Shakuda, Kyoto-shi (JP); Toshio Nishida, Kyoto-shi (JP); Masayuki Sonobe, Kyoto-shi (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 11/662,542

(22) PCT Filed: Sep. 12, 2005
(86) PCT No.: PCT/JP05/16752

§ 371 Date: Mar. 12, 2007

(30) Foreign Application Priority Data
Sep. 13, 2004 (JP) 2004-265464

(51) Int. Cl. H01L 33/00

(52) U.S. Cl. 257/88; 257/E33.001

(57) ABSTRACT

There is provided a semiconductor light emitting device which can prevent flickering in illumination due to an alternative current drive, and sensing incongruity at a time of turning off a switch, by providing anti-flickering means in itself, when it is assembled in an illumination device without any extra parts therein. A plurality of light emitting units (1) are formed, by forming a semiconductor lamination portion (17) by laminating semiconductor layers on a substrate (11) so as to form a light emitting layer, by electrically separating the semiconductor lamination portion (17) into a plurality of units, and by providing a pair of electrodes (19) and (20). The light emitting units (1) are respectively connected in series and/or parallel with a wiring film (3). A fluorescent layer (6) containing a fluorescent material having an afterglow time of 10 msec or more and 1 sec or less and/or a layer containing a phosphorescent glass material are formed at a light emitting surface side of the plurality of light emitting units (1).

### FIELD OF THE INVENTION

The present invention relates to a semiconductor light emitting device which has a plurality of light emitting units formed on a substrate and connected in series and/or parallel, which can be driven by an alternative current drive with commercial alternative current power sources of a voltage of, for example, 100 V, and which can be used in place of incandescent lamps or fluorescent lamps for illumination. More particularly, the present invention relates to a semiconductor light emitting device which has a structure capable of preventing flickering in illumination due to an alternative current drive.

### BACKGROUND OF THE INVENTION

Being accompanied with developing blue light emitting diodes (LEDs), the LEDs are lately used for light sources of displays or traffic signals and furthermore become to be used in place of incandescent lamps or fluorescent lamps. As it is preferable that the LEDs can be operated simply with an alternative current drive of 100 V or the like in case that the LEDs are used in place of the incandescent lamps or the fluorescent lamps, as shown, for example, in FIG. 7, a structure in which the LEDs connected in series and/or parallel are connected to an alternative current power source 71 is known well. Here, S represents a switch. In order to inhibit flickering caused by LEDs which are operated by only half waves and not operated by left half waves because of LEDs being diodes, it has been suggested to paint an inside surface of a cover for constituting an illumination device with a phosphorescent paint (cf. for example PATENT DOCUMENT 1).
PATENT DOCUMENT 1: Japanese Patent Application Laid-Open No. HEI10-083701

### DISCLOSURE OF THE INVENTION

### Problem to be Solved by the Present Invention

As described above, in an alternative current drive of LEDs, the LEDs operate and emit light while a voltage of a forward direction is applied but do not operate neither emit light while a voltage of a reverse direction is applied. Although LEDs can be operated at every half wave turn by turn by connecting the LEDs in parallel and in reverse direction, light is emitted intermittently because each of the LEDs operate individually and because an applied voltage increases gradually from 0 V. A repetition cycle of emitting light is two times of a cycle 50 Hz or 60 Hz in an alternative current by a commercial electric power source. Then, flickering is almost unnoticeable to human eyes but noticeable still to sensitive eyes.

On the other hands, in a light source for illumination, a method of setting LEDs in a housing and painting an inside surface of the housing with a phosphorescent paint needs a special treatment besides the LEDs, in which the casing or the like is necessary to be processed previously. Furthermore, if the phosphorescent paint has a long afterglow time, a sense of incongruity such that it remains light for a long period after turning off a switch arises as a problem.

The present invention is directed to solve the above-described problems and an object of the present invention is to provide a semiconductor light emitting device which can prevent flickering in illumination due to an alternative current drive, and sensing incongruity at a time of turning off a switch, by providing anti-flickering means in the light emitting device itself, when it is assembled in an illumination device without any extra parts therein.

Another object of the present invention is to provide a semiconductor light emitting device which can maintain brightness for long period after being turned off, like guide lamps, emergency illuminations in a power failure or the like, by the semiconductor light emitting device itself without having any relation to housings or the like.

### Means for Solving the Problem

A semiconductor light emitting device according to the present invention includes: a substrate; a semiconductor lamination portion formed on the substrate by laminating semiconductor layers so as to form a light emitting layer; a plurality of light emitting units formed by separating the semiconductor lamination portion electrically into a plurality of units, each of the plurality of light emitting units having a pair of electrodes; wiring films which are connected to the electrodes for connecting each of the plurality of light emitting units in series and/or parallel; and a fluorescent layer containing a fluorescent material having an afterglow time of 10 msec or more and 1 sec or less, the fluorescent layer being provided at a light emitting surface side (a surface side radiating light emitted in the light emitting layer) of the plurality of light emitting units.

Here, the afterglow time means a period in which an intensity of emitting light becomes approximately 1/10 after turning off an applied voltage to light emitting units.

The fluorescent material may be at least one member selected from a group including ZnS doped with Cu, Y₂O₃ and ZnS doped with Al.

By providing a layer containing a phosphorescent glass material on a surface of the fluorescent layer, an influence of flickering caused at a time of switching by the alternative current drive can be further prevented and the semiconductor light emitting device can be used in emergency lamps, guide lamps or the like depending on a purpose, by maintaining illumination for several ten minutes or more after being turned off. Here, the phosphorescent glass material means a material made by dispersing an inorganic or organic material having a phosphorescence property such as terbium in a glass body so as to have an afterglow time of one minute or more which is a period in which an intensity of emitting light becomes approximately 1/10 after turning off an applied voltage to light emitting units.

Another embodiment of the semiconductor light emitting device according to the present invention includes: a substrate; a semiconductor lamination portion formed on the substrate by laminating semiconductor layers so as to form a light emitting layer; a plurality of light emitting units formed by separating the semiconductor lamination portion electrically into a plurality of units, each of the plurality of light emitting units having a pair of electrodes; wiring films which are connected to the electrodes for connecting each of the plurality of light emitting units in series and/or parallel; and a layer containing a phosphorescent glass material, the layer being provided at a light emitting surface side (a surface side radiating light emitted in the light emitting layer) of the plurality of light emitting units.

The semiconductor lamination portion may be made of nitride semiconductor, and white light may be s emitted by being provided with a light color conversion member which converts a wavelength of light emitted in the light emitting layer to white light, and with at least one of a fluorescent material having an afterglow time of 10 msec or more and 1 sec or less and a phosphorescent material having an afterglow time of 1 sec or more, at least at a light emitting surface side of the semiconductor lamination portion. Thereby, the semiconductor light emitting device can prevent flickering and maintain emitting light for a long period after an electric power source is turned off, while being capable of being used for illumination.

The semiconductor lamination portion may be formed on a light transmitting substrate, a back surface of which is the light emitting surface side, and the light color conversion member and at least one of the fluorescent material and the phosphorescent material may be provided on the back surface of the substrate.

In addition, a resin layer which coats a semiconductor chip having the plurality of light emitting units may be mixed with at least one of a fluorescent material having an afterglow time of 10 msec or more and 1 sec or less and a phosphorescent material having an afterglow time of 1 sec or more, and also a layer containing at least one of a fluorescent material having an afterglow time of 10 msec or more and 1 sec or less and a phosphorescent material having an afterglow time of 1 sec or more may be provided on the resin layer.

### Effect of the Invention

According to the present invention, a fluorescent layer having an afterglow time of 10 msec to 1 sec and/or a layer containing a phosphorescent glass material having an afterglow time of 1 sec or more are provided at a light emitting surface side such as a surface of a semiconductor lamination portion in which a plurality of light emitting units are formed, or a back surface of a substrate or the like. Thereby, if the plurality of light emitting units emit light only at every half wave or at every repeated half wave by connecting light emitting units in inverse parallel in an alternative current drive, emission of light maintains by the fluorescent layer and/or the phosphorescent material during being turned off, and continuous emission of light can be obtained without receiving influence of turning on and off by an alternative current. The continuous illumination of light by the fluorescent layer or the phosphorescent glass material can be maintained sufficiently in case that light is emitted only at a half wave not by connecting diode of the light emitting units in inverse parallel, and flickering never appears.

Furthermore, by using a phosphorescent material having a long afterglow time of several minutes to several ten minutes, emission of light can be maintained for a very long period after turning off an electric power source, as a result, the semiconductor light emitting device can be used for emergency lamps, guide lamps or the like.

### BRIEF DESCRIPTION OF THE DRAWINGS

FIG. 1 is a fragmentary cross-sectional view explaining one embodiment of a semiconductor light emitting device according to the present invention;

FIG. 2 is a similar view to FIG. 1, explaining another embodiment of a semiconductor light emitting device according to the present invention;

FIG. 3 is a similar view to FIG. 1, explaining still another embodiment of a semiconductor light emitting device according to the present invention;

FIG. 4 is a cross-sectional view explaining still another embodiment of a semiconductor light emitting device according to the present invention;

FIG. 5 is a figure showing an example of arranging light emitting units of a semiconductor light emitting device according to the present invention;

FIG. 6 is a figure showing an equivalent circuit of FIG. 5;

FIG. 7 is a figure showing an example of a conventional circuit forming an illumination device by using LEDs.

### EXPLANATION OF LETTERS AND NUMERALS

1: light emitting unit

3: wiring film

4: electrode pad

6: fluorescent layer

7: layer containing a phosphorescent glass material

11: substrate

13: high temperature buffer layer

14: n-type layer

15: active layer

16: p-type layer

17: semiconductor lamination portion

17a: separation groove

18: light transmitting conductive layer

19: p-side electrode (upper electrode)

20: n-side electrode (lower electrode)

21: insulating film

### THE BEST EMBODIMENT OF THE PRESENT INVENTION

An explanation will be given below of a semiconductor light emitting device according to the present invention in reference to the drawings. As a cross-sectional view explaining an example is shown in FIG. 1, the semiconductor light emitting device according to the present invention is provided with a semiconductor lamination portion 17 formed on a substrate 11 by laminating semiconductor layers so as to form a light emitting layer and a plurality of light emitting units 1 formed by separating the semiconductor lamination portion 17 electrically into a plurality of units, each of which has a pair of electrodes 19 and 20. Each of the plurality of light emitting units 1 is connected to each other in series and/or parallel through wiring films 3 and provided with a fluorescent layer 6 containing a fluorescent material having an afterglow time of 10 msec or more and 1 sec or less at a light emitting surface side (a surface side radiating light emitted in the light emitting layer) of the plurality of light emitting units 1.

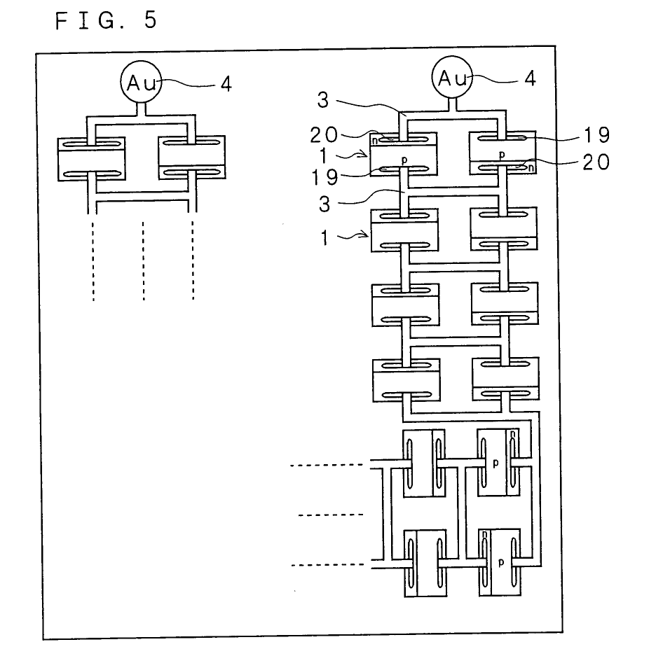

In the example shown in FIG. 1, the fluorescent layer 6 is provided on a back surface of the substrate 11 by forming a light emitting surface at a back surface side of the substrate 11 of the semiconductor lamination portion 17 laminated on the substrate 11. However, the fluorescent layer 6 may be provided on a surface at a top surface side of the semiconductor lamination portion 17 on which the wiring film 3 is formed and also may be provided at the top surface side of the semiconductor lamination portion as a resin package protecting the semiconductor lamination portion 17 or on a surface of the resin package, as described later in FIG. 4.

The fluorescent layer 6 is formed by mixing a fluorescent material having a certain afterglow time and a light transmitting resin material such as epoxy resin or the like and by coating it on a back side of the substrate 11 and curing. As a sense of incongruity such that it remains light for a long period after turning off a switch arises if a fluorescent material has a long afterglow time, the afterglow time (period in which brightness becomes approximately 1/10 after a voltage applied is turned off) is preferable to be 10 msec(millisecond) to approximately 1 sec. For example, ZnS:Cu(ZnS doped with Cu), Y₂O₃, ZnS:Al(ZnS doped with Al) or the like can be employed.

In the example shown in FIG. 1, the light emitting unit 1 (hereinafter referred as a LED, too) is formed by laminating nitride semiconductor layers and formed for a white light emitting device by providing a light color conversion member, not shown in figures, made of a fluorescent material such as YAG (Yttrium Aluminum Garnet) ( 1/10 afterglow time of 150 to 200 nsec), Sr—Zn—La or the like, conversing blue light absorbed to yellow light to make white light by mixing the yellow light and the blue light emitted from an LED chip. Therefor, the light color conversion member is also a fluorescent material, and it may be mixed in a light transmitting resin with another fluorescent material so as to have a desired afterglow. However, the light color conversion member may not be provided depending on a light color emitted in a light emitting units and a desired color of light. In other words, the fluorescent layer according to the present invention is a layer containing a fluorescent material having an afterglow time of 10 msec to 1 sec, inhibits flickering to eyes by afterglow and realizes a semiconductor light emitting device emitting light of a desired color by mixing a light color conversion member different from a fluorescent material for light color conversion. Of course, these may be provided independently.

In the example shown in FIG. 1, as described above, the light emitting units 1 are formed as the light emitting device emitting white light, by forming the light emitting unit 1 (hereinafter, referred to as simply “LED”, too) by laminating nitride semiconductor layers and by providing the light color conversion member. Therefor, the semiconductor lamination portion 17 is formed by laminating nitride semiconductor layers. However, white light can be obtained by forming light emitting units of three primary colors, red, green and blue, too, and light emitting units with a desired light color can be also formed because white light is not always necessary. In addition, in the example shown in FIG. 1, in order to prevent problems of disconnection or increase of resistance of the wiring film because of thin film caused by a level difference of the wiring film 3, a separation groove 17a separating each of the light emitting units 1 is formed so that surfaces of the semiconductor lamination portion in both sides of the separation groove 17a are in a substantially same plane. If the separation groove 17a is formed in a part of surfaces in the substantially same plane, the wiring film 3 can be formed without the level difference by forming the separation groove 17a as narrow as a width capable of an electrical insulation, even if recesses occur on the insulating film deposited therein.

Here, the substantially same plane does not mean a perfectly same plane, but means surfaces whose level difference is within a level of not raising a problem of a step-coverage caused by the level difference in the event of forming the wiring film and concretely exhibits a level difference of both surfaces is approximately 0.3 μm or less. Further, the nitride semiconductor means a compound of Ga of group III element and N of group V element or a compound (nitride) in which a part or all of Ga of group III element is substituted by other element of group III element like Al, In or the like and/or a part of N of group V element is substituted by other element of group V element like P, As or the like.

As sapphire (single crystal Al₂O₃) or SiC is generally used for the substrate 11 in case of laminating the nitride semiconductor, the sapphire (single crystal Al₂O₃) is used in the example shown in FIG. 1. But a substrate is chosen from view point of a lattice constant or a thermal expansion coefficient depending upon semiconductor layers to be laminated on.

The semiconductor lamination portion 17 laminated on the substrate 11 made of sapphire is formed by laminating following layers in order: a low temperature buffer layer 12 made of GaN and having a thickness of approximately 0.005 to 0.1 μm; a high temperature buffer layer 13 made of un-doped GaN and having a thickness of approximately 1 to 3 μm; an n-type layer 14 formed thereon, having a thickness of approximately 1 to 5 μm, composed of a contact layer made of an n-type GaN doped with Si and a barrier layer (a layer with a large band gap energy) made of an n-type AlGaN based compound semiconductor doped with Si, or the like; an active layer 15 which has a structure of a multiple quantum well (MQW) formed in a thickness of approximately 0.05 to 0.3 μm by laminating 3 to 8 pairs of well layers made of a material having a band gap energy lower than that of the barrier layer, for example In_{0.13}Ga_{0.87}N and having a thickness of 1 to 3 nm, and barrier layers made of GaN and having a thickness of 10 to 20 nm; and a p-type layer 16 formed with a p-type barrier layer (a layer with a large band gap energy) made of a p-type AlGaN based compound semiconductor and a contact layer made of a p-type GaN, and having a thickness of approximately 0.2 to 1 μm in total.

In the example shown in FIG. 1, the high temperature buffer layer 13 is formed with GaN which is un-doped and semi-insulating. In case that the substrate is made of an insulating substrate like sapphire, it is not always necessary for the high temperature buffer layer to be semi-insulating because there is no problem if the separation groove is etched up to the substrate as described later, but the un-doped layer is preferable because a crystal structure of the semiconductor layer laminated on that is superior and further, by providing with semi-insulating semiconductor layers, the electrical separation can be obtained without etching up to the substrate surface when each of the light emitting units is separated. And in case that the substrate 11 is made of a semiconductor substrate like SiC, it is necessary to form the high temperature buffer layer 13 with un-doped and semi-insulating, for separating adjacent light emitting portions electrically and for making each of light emitting units independent.

The n-type layer 14 and the p-type layer 16 contain two kinds of the barrier layer and the contact layer in the above-described example, but only a GaN layer can be used sufficiently, although it is preferable with an aspect of carrier confinement effect to form a layer including Al at a side of the active layer 6. And, these can be formed with other nitride semiconductor layers or other semiconductor layers can be interposed. Although, in this example, a double hetero structure is shown in which the active layer 15 is sandwiched by the n-type layer 14 and the p-type layer 16, a structure of a p-n junction can be used in which the n-type layer and the p-type layer are directly joined. Further, although the p-type AlGaN based compound layer is formed directly on the active layer 15, an un-doped AlGaN based compound layer of approximately several nanometer thicknesses can be laminated on the active layer 15. Thereby, a leakage caused by a contact of the p-type layer and the n-type layer can be avoided while embedding pits created in the active layer 15 by forming a pit-creating layer under the active layer 15.

The light transmitting conductive layer 18 which is formed with, for example, ZnO or the like and makes an ohmic contact with the p-type semiconductor layer 16 is formed in a thickness of approximately 0.01 to 0.5 μm on the semiconductor lamination portion 17. A material of this light transmitting conductive layer 18 is not limited to ZnO, ITO (Indium Tin Oxide) or a thin alloy layer of Ni and Au having a thickness of approximately 2 to 100 nm can be used and diffuse current to whole part of a chip while transmitting light. A part of the semiconductor lamination portion 17 is etched so as to expose the n-type layer 14, and the separation groove 17a is formed by further etching the semiconductor lamination portion 17 in the vicinity of the exposed portion of the n-type layer 14 parting by an interval d. The reason why the separation groove 17a is formed at a position apart from the exposed portion of the n-type layer 14 with the distance d, not forming in the exposed portion of the n-type layer 14, is preventing a level difference of the wiring film 3 at a portion of the separation groove 17a from becoming large by being accompanied with increasing a width of the separation groove 17a and the exposed portion of the n-type layer 14. However, in the present invention, it is not indispensable to provide the distance d.

In case of providing the distance d, the spaced part of the distance is a dummy region 5 not contributing to emitting light region (portion of a length L1) and the interval d is set in a range of approximately 1 to 50 μm depending on a purpose because the region can be used as a space for making a heat dispersion portion or forming a wiring film as described later. The separation groove 17a is formed by a dry etching technique or the like, in a narrow width which electrical separation can be achieved, approximately 0.6 to 5 μm, for example approximately 1 μm (in a depth of approximately 5 μm).

Thereafter, a p-side electrode (upper electrode) 19 is formed on a part of a surface of the light transmitting conductive layer 18 with a lamination structure of Ti and Au, and an n-side electrode (lower electrode) 20 for a ohmic contact is formed on the n-type layer 14 exposed by removing a part of the semiconductor lamination portion 17 by etching with a Ti—Al alloy. In the example shown in FIG. 1, the lower electrode 20 is formed in a thickness of approximately 0.4 to 0.6 μm so as to be as almost same high as the upper electrode 19 is, in order to make the level difference of the wiring film 3 as small as possible. However, the lower electrode 20 is not necessary to be formed in the almost same height to the upper electrode 19, but may be in a usual height, since level difference is not formed so much because the wiring film 3 is deposited on the lower electrode 20 by evaporation or the like. On the other hand, as reliability of the wiring film is improved when the thickness of the lower electrode 20 is thicker than that of the upper electrode 19, the lower electrode 20 is preferably as almost same high as the upper electrode 19.

Then, an insulating film 21 made of SiO₂ or the like is provided on an exposed surface of the semiconductor lamination portion 17 and inside of the separation groove 17a so as to expose surfaces of the upper electrode 19 and the lower electrode 20. As a result, a plurality of the light emitting units 1 separated by the separation groove 17a are formed on the substrate 11. On a surface of the insulating film 21, an n-side electrode 20 of one light emitting unit 1a and a p-side electrode 19 of an light emitting unit 1b adjacent to the light emitting unit 1a are connected with the wiring film 3. The wiring film 3 is formed in a thickness of approximately 0.3 to 1 μm by depositing a metal film of Au, Al or the like by evaporation, sputtering or the like. The wiring film is formed so as to connect each of the light emitting units 1 in a desired manner, in series or parallel.

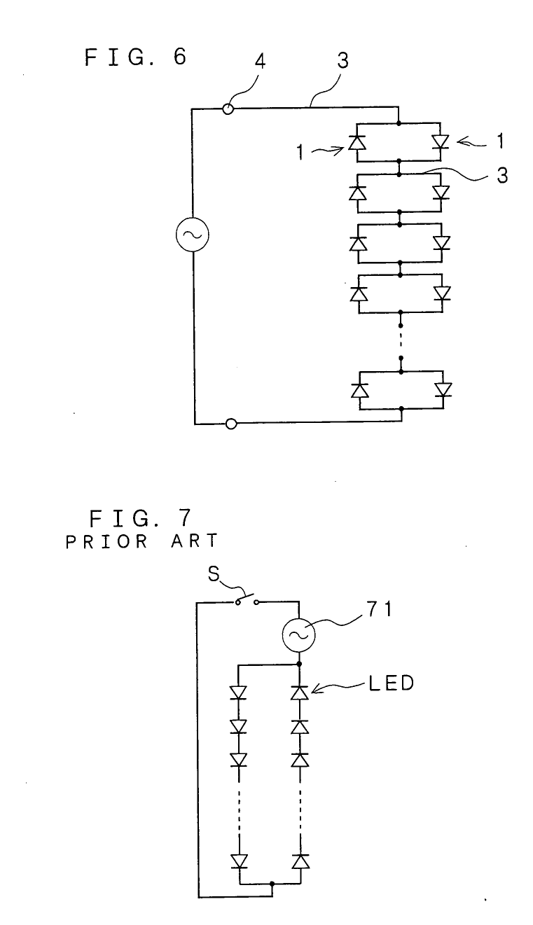

For example, as shown in FIG. 1, a bright light source driven with 100 V AC or the like can be obtained by connecting sequentially the n-side electrode 20 of one light emitting unit 1a and the p-side electrode 19 of the adjacent light emitting unit 1b, separated by the separation grooves 17a, respectively in order, and by connecting light emitting units to a number of making a total voltage of operation voltages 3.5 to 5 V per one light emitting unit near a voltage of commercial electric power sources such as 100 V or the like (a precise adjustment is made by adding a resistor or a capacitor in series), and connecting the groups in parallel in reverse directions of p-side and n-side. As an example of arranging light emitting units 1 is shown in FIG. 5, pairs of light emitting units connected in parallel in reverse direction of p-n junction can be connected in series to a number of making a total operation voltage approximately 100V AC. The above described structure is represented by an equivalent circuit shown in FIG. 6. And if a luminance by this connection is not sufficient, more groups of the same type can be connected in parallel. As shown in FIG. 5, in case of connecting, in series, a set of two light emitting units connected to each other in inverse parallel, it is necessary to connect the n-side electrode 20 and the p-side electrode 19 with the wiring film 3 between the light emitting units adjacent to each other not in a longitudinal direction but in a lateral direction, and a space for forming the wiring film 3 is required between the light emitting units 1. The dummy region 5 described above may be formed in a necessary width for the space.

And next, an explanation on a method for manufacturing the semiconductor light emitting device with a structure shown in FIG. 1 will be given below. The semiconductor lamination portion is formed by a method of metal organic compound vapor deposition (MOCVD), supplying necessary gasses such as a reactant gas like trimethyl gallium (TMG), ammonia (NH₃), trimethyl aluminium (TMA), trimethyl indium (TMI) or the like, and a dopant gas like SiH₄ for making the n-type, or a dopant gas like biscyclopentadienyl magnesium (Cp₂Mg) for making the p-type.

At first, for example, the low temperature buffer layer 12 made of a GaN is deposited with a thickness of approximately 0.005 to 0.1 μm on the sapphire substrate 11, for example, at a temperature of approximately 400 to 600° C., thereafter, the high temperature buffer layer 13 of semi-insulating and made of an un-doped GaN with a thickness of approximately 1 to 3 μm and the n-type layer 14 formed of the GaN layer doped with Si and the AlGaN based compound semiconductor layer doped with Si with a thickness of approximately 1 to 5 μm are formed, at an elevated temperature of for example approximately 600 to 1200° C.

And at a lowered temperature of 400 to 600° C., the active layer 6 is formed which has a structure of a multiple quantum well (MQW) formed with a thickness of approximately 0.05 to 0.3 μm by laminating 3 to 8 pairs of well layers made of, for example, In_{0.13}Ga_{0.87}N and having a thickness of 1 to 3 nm, and barrier layers made of GaN and having a thickness of 10 to 20 nm.

And, elevating a temperature in a growth furnace to approximately 600 to 1200° C., the p-type layer 16 including the p-type AlGaN based compound semiconductor layer and GaN layer are laminated 0.2 to 1 μm thick in total.

After forming a protective film made of Si₃N₄ or the like and annealing at a temperature of approximately 400 to 800° C. for 10 to 60 minutes to activate the p-type dopant, a light transmitting conductive layer 18 is formed on a surface with, for example, a ZnO layer approximately 0.1 to 0.5 μm thick by a method of MBE, sputtering, evaporation, PLD, ion plating or the like. Successively, in order to form the n-type electrode 20, a part of the semiconductor lamination portion 17 is etched by a method of a reactive ion etching with chlorine gas so as to expose the n-type layer 14. Further subsequently, the semiconductor lamination portion 17 is etched with a width w of approximately 1 μm and reaching the high temperature buffer layer 13 of the semiconductor lamination portion 17, in the vicinity of the exposed portion of the n-type layer 14 and away from the exposed portion of the n-type layer 14, in order to separate each of the light emitting units 1 electrically by a dry etching technique similarly. The interval d between the exposed portion of the n-type layer 14 and the separation groove 17a is set, for example, approximately 1 μm.

Subsequently, the n-side electrode 20 is formed on the exposed surface of the n-type layer 14 by depositing Ti and Al continuously with a thickness of approximately 0.1 and approximately 0.3 μm respectively by a method of sputtering or evaporating, and by RTA heating at approximately 600° C. for 5 minutes to make an alloy. Then, if the n-side electrode is formed by using a method of lift-off, the n-side electrode of a desired shape can be formed by removing a mask. Thereafter, the insulating film 21 made of SiO₂ or the like is formed on the entire surface and a part of the insulating film 21 is etched and removed so as to expose surfaces of the p-side electrode 19 and the n-side electrode 20. A desired wiring film 3 is formed by the method of lift-off or the like removing the photo resist film, after providing a photo resist film having openings only at connecting positions where the p-side electrode 19 and the n-side electrode 20 exposed are connected, depositing an Au film, Al film or the like by evaporating.

Then, a fluorescent layer 6 is formed by painting a light transmitting resin such as an epoxy resin mixed with a fluorescent material having an afterglow time of 10 msec to 1 sec, for example ZnS:Cu, or the like and by being solidified by drying. A chip of the semiconductor light emitting device, whose partial cross-sectional view and schematic plan view are shown in FIGS. 1 and 5, can be obtained by dividing a wafer into chips having a plurality of light emitting units 1. In addition, at a time of forming the wiring films 3, the electrode pads 4 for connecting to external power supply is formed of same material as that of the wiring films 3 simultaneously as shown in FIG. 5.

In the example shown in FIG. 1, since the exposed part of the n-type layer 14 for forming the n-side electrode 20 and the separation groove 17a for separating between the light emitting units 1 are formed at different positions even though they are near each other (a width of the dummy region 5 can be widened depending on a purpose), and since, moreover, as the n-side electrode 20 is formed high, it is not necessary that the wiring film 3 connecting the n-side electrode 20 and the p-side electrode 19 between adjacent light emitting units 1, makes connection through a large level difference, even though being formed through the separation groove 17a. In other words, a depth of the separation groove 17a is approximately 3 to 6 μm, but the width is very narrow such as approximately 0.6 to 5 μm, for example approximately 1 μm. Therefor, even if the separation groove 17a is not filled up with the insulating film 21 perfectly, a surface is almost closed and a large level difference does not occur in the wiring film 3, even some recess is formed. Thereby, problems of a step-coverage never occur and a semiconductor light emitting device provided with wiring films 3 having very high reliability can be obtained.

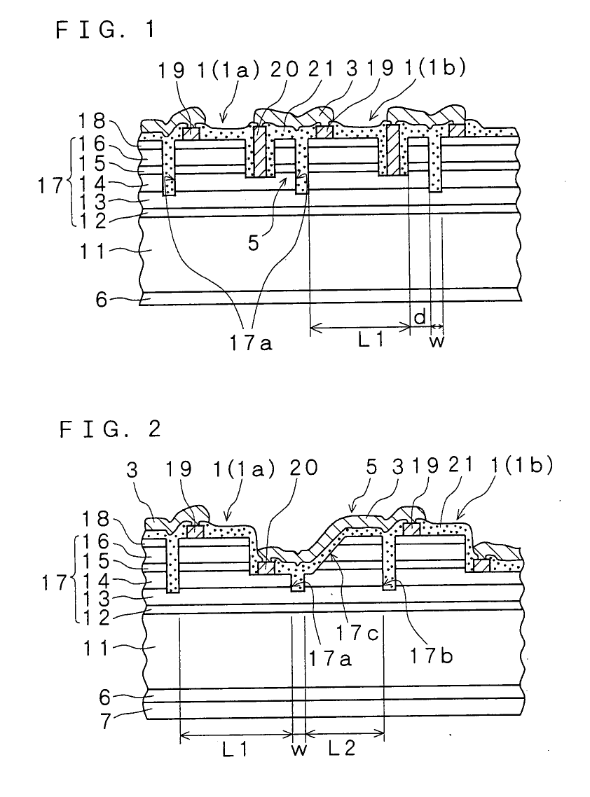

In the above-described example, surfaces of semiconductor layers in both sides of the separation groove 17a are formed in a substantially same plane by forming the exposed portion of the n-type layer 14 and the separation groove 17a at different places, however, even if the separation groove 17a is formed at an exposed portion continuously near the n-type layer 14 exposed, a problem of disconnection can be inhibited by providing a dummy region having an inclined surface (intermediate region). The example is explained by a similar cross-sectional view shown in FIG. 2. In addition, in the example shown in FIG. 2, not only an arrangement of a structure of the light emitting units 1, but also a layer 7 containing a phosphorescent glass material is further provided on a surface of the fluorescent layer 6.

The phosphorescent glass is a glass body mixed with a phosphorescent material such as terbium or the like and can be provided on a desired portion by mixing powder of the phosphorescent glass into a light transmitting resin and by coating it. Since an afterglow time can be adjusted by adjusting a density and a thickness of coating, the flickering caused by alternative current drive is eliminated perfectly, for example, by adjusting the afterglow time to approximately several seconds which complement an afterglow of the fluorescent layer having an afterglow of a very short period. And the light emitting device can be obtained for guide lamps or emergency lamps by adjusting the afterglow time approximately from 30 to 120 min. In addition, there is a merit such that absorption of light is reduced by providing the layer containing the phosphorescent glass on the fluorescent film 6, as shown in FIG. 2, even though depending on the fluorescent material when phosphorescent light is main light emission.

In FIG. 2, as the semiconductor lamination portion 17 is same as that in FIG. 1, same letters and numerals are attached and explanations are omitted. In this example, the separation groove 17a is formed not from the surface of the semiconductor lamination portion 17 but from the exposed surface of the n-type layer 14 so as to reach the high temperature buffer layer 13. But, an exposed portion of the n-type layer 14 is formed at an opposite place to a side of forming the n-type electrode 20 intervening the separation groove 17a, and it is characterized in that a dummy region 5 having an inclined surface 17c is formed, which extends from the exposed portion of the n-type layer 14 to a surface of the light transmitting conductive layer 18 on the semiconductor lamination portion 17.

The dummy region 5 is formed between one light emitting unit 1a and an adjacent light emitting unit 1b and in a width L2 of approximately 10 to 50 μm. Here, a width L1 of the light emitting unit 1 contributing to light emitting is approximately 60 μm. In addition, in the dummy region 5, the inclined surface 17c is formed from the exposed portion of the n-type layer 14 to the surface of the semiconductor lamination portion 17 as shown in FIG. 2. Although FIG. 2 is not accurate in dimensions but shows only schematic figure of the structure, the level difference between a surface of the light transmitting conductive layer 18 and the n-type layer 14 is approximately 0.5 to 1 μm as described above, and a distance from the exposed surface of the n-type layer 14 to a bottom of the separation groove 17a is approximately 3 to 6 μm. However, as the width w of the separation groove 17a is approximately 1 μm, at least a surface of the separation groove 17a is almost filled up with the insulating layer 21 even if some recess occurs. Then, if the wiring film 3 is formed through the exposed surface of the n-type layer 14 of the dummy region 5, problems of step-coverage can be almost solved, further, the inclined surface 17c of the dummy region 5 as shown in the example of FIG. 2 is more preferable for reliability. By this, as the insulation film 21 and the wiring film 3 have a gentle slope, reliability of the wiring film 3 can be more improved.

In order to form such inclined surface 17c, masking with a photo resist film or the like except a portion where the inclined surface is formed, and etching with a method of dry etching while inclining the substrate 11 obliquely are carried out, and then the inclined surface 17c shown in FIG. 2 can be formed. After that, the semiconductor light emitting device of a structure shown in FIG. 2 can be formed, in a same manner shown in FIG. 1, by forming the p-side electrode 19 and the n-side electrode 20, forming the insulating film 21 so as to expose surfaces of the electrodes, forming the wiring films 3, and forming the fluorescent layer 6 and the layer 7 containing a phosphorescent glass.

By forming this dummy region 5, besides that the inclined surface 17c described above can be formed, although the dummy region 5 itself does not contribute to emitting light, light emitted at an adjacent light emitting unit 1 and transmitted through semiconductor layers can be radiated from a surface or a side of the dummy region 5, and light emitting efficiency (output to input) can be improved compared to the case that the light emitting units 1 are continuously formed. When the light emitting units 1 are continuously formed, as dissipation of heat generated by energizing is hard, there exists probability of decreasing light emitting efficiency and deteriorating reliability, after all. However, it is preferable to form such dummy region 5 not emitting light from the view point of reliability, because the dummy region does not generate heat but dissipates heat easily. As shown in FIG. 5, in case of connecting two light emitting units 1 arranged in a lateral position with the wiring film 3, a space for forming the wiring film 3 is necessary. Here, the wiring film 3 can be formed on the dummy region 5, and the dummy region may be used as a space to form accessory parts such as an inductor, a capacitor, a resistor (which may be used as a series resistance for fitting to 100 V operation) or the like. In addition, as there exists a space for forming a wiring film freely, it becomes a merit to form a structure of the light emitting unit 1 itself in a desired shape easily such as a circular shape (shape of a top view) or the like instead of a quadrilateral shape, considering a structure for taking light out. Namely, not only inhibitions of disconnection of the wiring film, but also kinds of merits are accompanied. This way of utilizing the dummy region 5 may be used similarly in the example in FIG. 1.

In the example shown in FIG. 2, between the dummy region 5 and the light emitting unit 1 adjoining at a high side of the semiconductor lamination portion 17, a second separation groove 17b is formed from the surface of the semiconductor lamination portion 17 and reaching to a high temperature buffer layer 13. The second separation groove 17b is also formed at a position where surfaces of the semiconductor lamination portion is in substantially same plane, and formed in an interval as narrow as a width capable of an electrical insulation same as described above, namely approximately 1 μm. Then, if the wiring film 3 is formed on the second separation groove 17b through the insulating film 21, problem of disconnection or the like does not arise. Although the second separation groove 17b may not be formed, electrical separation between adjacent light emitting units 1 can be secured certainly, and reliability of separation is improved by forming the second separation groove 17b, even if the separation groove 17a does not reach the high temperature buffer layer 13 because of variance of etching.

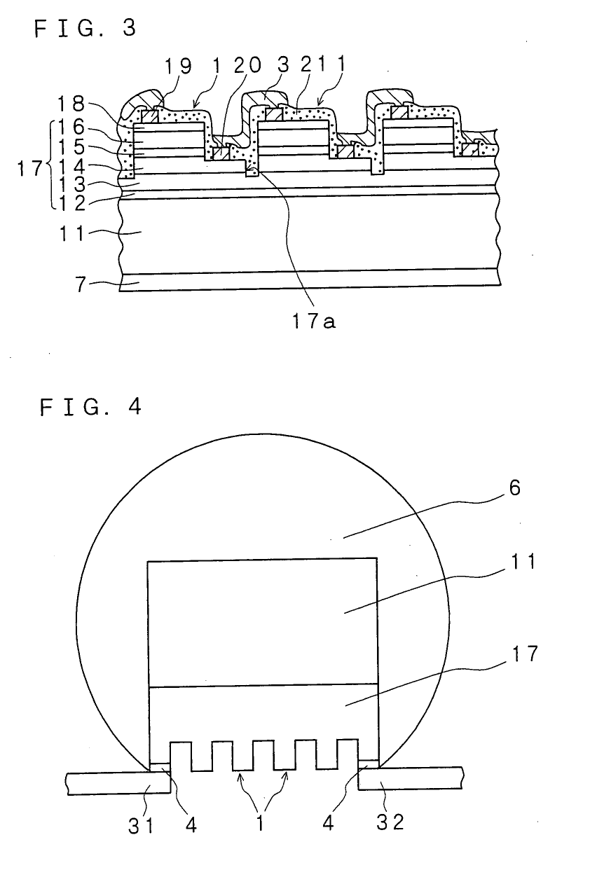

FIG. 3 shows still another example of forming the wiring film 3 in which a layer 7 containing a phosphorescent glass material is formed on a back surface of the substrate 11 directly without a fluorescent layer. In other words, in case of illumination lamps in which an afterglow after turning off an electric power source does not matter and which are used in lamps for emergency or guide, it is not necessary to provide a fluorescent layer having a short afterglow time such as 1 msec or less, and the purpose can be achieved by providing the layer 7 containing the phosphorescent glass having a long afterglow time of several minutes or more. The example is shown in FIG. 3.

Further, in this example, the separation groove 17a separating each of the light emitting units is not formed at a part of a surface of the semiconductor layer in the substantially same plane, but formed on an end portion of the exposed surface of the n-type layer 14. In this case, recesses such as separation grooves or the like may be filled up by forming an insulating film which has a property of withstanding to a heat of approximately 400° C., transparency and insulating property in the separation groove 17a, for example, by employing a product “spinfil 130” manufactured by Clariant Japan K.K. which is processed by spin coating and curing at 200° C. for 10 min and at 400° C. for 10 min, and the semiconductor light emitting device can be obtained because the level difference does not make problems so much even in forming the wiring film 3 directly from the exposed surface of the n-type layer to a layer of an upper electrode 19. In such manner, if the problems of the level difference caused by the separation groove 17a can be solved, the surfaces of the semiconductor layers in both sides of the separation groove 17a are not always indispensable to be in a substantially same plane. Here, as a structure of the semiconductor lamination portion 17 except a position of the separating groove 17a and a structure of the wiring films 3 is same as that of the examples shown in FIG. 1 or FIG. 2, the same letters and numerals are attached to the same parts and explanations are omitted.

FIG. 4 shows another embodiment of the semiconductor light emitting device according to the present invention. Although, in any of the examples shown in FIGS. 1 to 3, the fluorescent layer 6 or the layer 7 containing the phosphorescent glass are formed on a back surface of the substrate 11, since the fluorescent layer 6 or the like is required to be formed at a light emitting side, it may be formed at a top surface side of the semiconductor lamination portion 17 (through a surface of the wiring film 3 or other resin layers) and also the fluorescent layer 6 formed may be formed in a desired shape, as shown in FIG. 4, by mixing the above-described fluorescent material in a resin for coating the semiconductor lamination portion 17.

FIG. 4 shows an example of the light emitting device in which the fluorescent material having the above-described afterglow property is mixed in a light transmitting resin such as an epoxy resin or the like. Here, the light emitting device is formed by forming a semiconductor lamination portion 17 on the substrate 11 shown in FIGS. 1 to 3, forming a resin layer of a desired shape such as a dome shape, a sphere shape or the like for a package which packages a semiconductor chip formed by connecting a plurality of light emitting units 1 in a pattern shown in FIG. 5 or the like with the wiring films 3 and connected to external wirings 31 and 32 and forming the fluorescent layer 6 by mixing the fluorescent material in the resin layer. In FIG. 4, the light emitting units 1 are shown schematically by omitting the wiring film or the like, but the structure of each of the light emitting units 1 is similar to that of examples shown in FIGS. 1 to 3. The external wirings 31 and 32 connected to the pair of electrode pads are also shown schematically, and it is needless to say that they may be formed in a shape of electric bulb sockets.

As shown in FIGS. 1 to 4, in case that the back surface side of the substrate 11 is a primary light emitting surface, the light need not to emit toward a side of forming the wiring films 3 and a metal film or the like maybe formed on the almost entire surface. It is rather preferable to form a layer reflecting light. On the contrary, in case that the side of forming the wiring films 3 is the primary light emitting surface, it is preferable to form the wiring films 3 as narrow as possible to prevent blocking light or to form with a light transmitting layer such as ITO or the like. In addition, in the examples shown in FIGS. 1 to 3, different structures of the light emitting units 1 and different arrangements of the fluorescent layer 6 are shown at the same time, the structures of the light emitting units 1 and the arrangements of the fluorescent layer 6 can be combined arbitrarily.

As described above, according to the present invention, since a fluorescent layer and/or a layer containing a phosphorescent glass material are provided in a semiconductor light emitting device itself, a sense of discomfort caused by flickering by an alternative current drive is inhibited perfectly without a sense of incongruity caused by too long afterglow by a structure in which only a fluorescent layer is provided. In addition, the flickering can be inhibited perfectly by providing a layer containing the phosphorescent glass material, and, at the same time, the semiconductor light emitting device can be used in emergency lamps or guide lamps by providing the layer containing a phosphorescent glass material having a longer afterglow time. As a result, in case of using for illumination devices, an illumination device having no flickering even in an alternative current drive can be obtained and used in emergency lamps at a power failure only by setting the semiconductor light emitting device, in which a fluorescent layer or a layer containing a phosphorescent glass material is provided depending on a purpose, directly at a necessary place.

### INDUSTRIAL APPLICABILITY

The light emitting device can be used for kinds of illumination devices such as ordinary illumination device in place of fluorescent lamps by using commercial alternative current power sources and traffic signs or the like.

What is claimed is:

1. A semiconductor light emitting device comprising:
a substrate;
a semiconductor lamination portion formed on the substrate by laminating semiconductor layers so as to form a light emitting layer;
a plurality of light emitting units formed by separating the semiconductor lamination portion electrically into a plurality of units, each of the plurality of light emitting units having a pair of electrodes;
wiring films which are connected to the electrodes for connecting each of the plurality of light emitting units in series and/or parallel; and
a fluorescent layer containing a fluorescent material having an afterglow time of 10 msec or more and 1 sec or less, the fluorescent layer being provided at a light emitting surface side of the plurality of light emitting units.

2. The semiconductor light emitting device according to claim 1, wherein the fluorescent material is at least one member selected from a group comprising ZnS doped with Cu, Y₂O₃ and ZnS doped with Al.

3. The semiconductor light emitting device according to claim 1, wherein a layer containing a phosphorescent glass material is provided on a surface of the fluorescent layer.

4. A semiconductor light emitting device comprising:
a substrate;
a semiconductor lamination portion formed on the substrate by laminating semiconductor layers so as to form a light emitting layer;
a plurality of light emitting units formed by separating the semiconductor lamination portion electrically into a plurality of units, each of the plurality of light emitting units having a pair of electrodes;
wiring films which are connected to the electrodes for connecting each of the plurality of light emitting units in series and/or parallel; and
a layer containing a phosphorescent glass material, the layer being provided at a light emitting surface side of the plurality of light emitting units.

5. The semiconductor light emitting device according to claim 4, wherein the phosphorescent glass material is a glass material mixed with terbium.

6. The semiconductor light emitting device according to claim 1, wherein the semiconductor lamination portion is made of nitride semiconductor, and white light is emitted by being provided with a light color conversion member which converts a wavelength of light emitted in the light emitting layer to white light, and with at least one of a fluorescent material having an afterglow time of 10 msec or more and 1 sec or less and a phosphorescent material having an afterglow time of 1 sec or more, at least at a light emitting surface side of the semiconductor lamination portion.

7. The semiconductor light emitting device according to claim 6, wherein the semiconductor lamination portion is formed on a light transmitting substrate, a back surface of which is the light emitting surface side, and the light color conversion member and at least one of the fluorescent material and the phosphorescent material are provided on the back surface of the substrate.

8. The semiconductor light emitting device according to claim 1, further comprising:
a resin layer coating a semiconductor chip having the plurality of light emitting units,
wherein the resin layer is mixed with at least one of a fluorescent material having an afterglow time of 10 msec or more and 1 sec or less and a phosphorescent material having an afterglow time of 1 sec or more.

9. The semiconductor light emitting device according to claim 1, further comprising:
a resin layer coating a semiconductor chip having the plurality of light emitting units, and
a layer containing at least one of a fluorescent material having an afterglow time of 10 msec or more and 1 sec or less and a phosphorescent material having an afterglow time of 1 sec or more provided on the resin layer.

10. The semiconductor light emitting device according to claim 8, wherein the semiconductor lamination portion is made of nitride semiconductor and white light is emitted by mixing a light color conversion member converting a wavelength of light emitted in the light emitting layer to white light in the resin layer.
